(19) United States
(12) Patent Application Publication
(10) Pub. No.: US 2011/0083719 A1
(43) Pub. Date: Apr. 14, 2011

(54) ELECTRONIC DEVICE

(75) Inventors: Harumi Takada, Kanagawa (JP); Masahiro Morooka, Kanagawa (JP); Reiko Yoneya, Kanagawa (JP); Masaki Orihashi, Kanagawa (JP); Cheng Zhu, Kanagawa (JP); Yusuki Suzuki, Kanagawa (JP); Kazuhiro Noda, Kanagawa (JP)

(73) Assignee: SONY CORPORATION

(21) Appl. No.: 12/999,254

(22) PCT Filed: Jun. 24, 2009
(86) PCT No.: PCT/JP2009/061449

§ 371 Date: Dec. 22, 2010

(30) Foreign Application Priority Data
Jun. 24, 2008 (JP) 2008-164447

(51) Int. Cl. H01L 31/12

(52) U.S. Cl. 136/244

(57) ABSTRACT

The present invention relates to an electronic device configured to make use of features in terms of design quality and flexibility of a dye-sensitized solar cell. A solar cell-cum-display unit 61 has both a function of a solar cell and a function of a display unit that displays a predetermined display body, allows a predetermined character string such as “PONY” to be indentified, generates electric power from illuminating light or sunlight, and stores the electric power in a storage battery 62. A light source 63 such as a fluorescent lamp radiates light to the solar cell-cum-display unit 61 by the electric power stored in the storage battery 63, whereby the features of the dye-sensitized solar cell can be made use of. The present invention is applicable to a device including a dye-sensitized solar cell.

### TECHNICAL FIELD

The present invention relates to an electronic device including a photoelectric conversion element.

### BACKGROUND ART

Recently, researches into dye-sensitized solar cells as next-generation solar cells which will replace silicon (Si)-based solar cells or the like have been widely conducted.

The dye-sensitized solar cells have features such as a simple production process thereof and an ability to be provided with design quality. As for an example of design quality, a solar cell having a plurality of colors would be able to be installed without impairing the external appearances of a device, a building, or the like on which the solar cell is to be installed. It is believed that this leads to further spread of solar cells.

For example, PTL 1 and PTL 2 are known as this type of dye-sensitized solar cells.

### CITATION LIST

### Patent Literature

PTL 1: Japanese Unexamined Patent Application Publication No. 2006-221965
PTL 2: Japanese Unexamined Patent Application Publication No. 2005-182076

### SUMMARY OF INVENTION

### Technical Problem

Meanwhile, since the dye-sensitized solar cells have features such as design quality and flexibility, which are not realized by hitherto used solar cells made of silicon or the like, there has been an increasing desire to use the dye-sensitized solar cells in applications in which these features are made use of.

For example, in the invention disclosed in PTL 1, in the case where a solar cell unit including a dye-sensitized solar cell is attached to a display unit of a road sign or the like, the solar cell unit is merely attached to the upper surface of the display unit. Therefore, the solar cell unit and the display unit are completely separately provided. Consequently, there may be problems that the volume as a whole is increased and the structure thereof also becomes complex, and that the resulting scenery provides an uncomfortable feeling. Thus, the features of the dye-sensitized solar cell have not been made use of.

Furthermore, also in the invention disclosed in PTL 2, a solar cell and a liquid crystal display device function in a state in which they are separately connected, and thus the features of the dye-sensitized solar cell are not made use of, similarly to the invention described in the above literature.

The present invention has been made in view of the above situation. The present invention is configured to be able to make use of the design quality, flexibility, and the like which are features of the dye-sensitized solar cell.

### Solution to Problem

An electronic device according to a first aspect of the present invention includes a photoelectric conversion element including a predetermined display body formed by adsorbing a predetermined dye onto a semiconductor electrode.

The electronic device further includes a light source that irradiates the display body, in which the photoelectric conversion element generates electric power from light radiated from the light source and supplies the electric power to the light source, and the light source is driven by the electric power supplied from the photoelectric conversion element.

The electronic device further includes a power storage unit that stores the electric power generated by the photoelectric conversion element, in which the photoelectric conversion element generates electric power from light radiated from the light source and stores the electric power in the power storage unit, and the light source is driven by the electric power stored in the power storage unit.

The display body represents a character, a number, a symbol, a figure, or any combination thereof.

The photoelectric conversion element is a dye-sensitized solar cell.

An electronic device according to a second aspect of the present invention includes a photoelectric conversion element formed on a substrate that can be attached to and detached from an object having a predetermined shape.

The substrate is a film that can be attached and detached any number of times.

The photoelectric conversion element is attached to a window or a tile with the substrate therebetween, generates electric power from sunlight or illuminating light, and supplies the electric power to a power storage unit installed in the mobile device connected to the photoelectric conversion element.

The electronic device further includes a power storage unit that stores electric power generated by the photoelectric conversion element.

The photoelectric conversion element includes a predetermined display body formed by adsorbing a predetermined dye onto a semiconductor electrode.

The display body represents a character, a number, a symbol, a figure, or any combination thereof.

The photoelectric conversion element is a dye-sensitized solar cell.

### ADVANTAGEOUS EFFECTS OF INVENTION

As described above, according to an aspect of the present invention, the features of the dye-sensitized solar cell can be made use of.

### BRIEF DESCRIPTION OF DRAWINGS

FIG. 1 includes cross-sectional views illustrating a step of performing a dye adsorption treatment to which the present invention is applied.

FIG. 2 includes views illustrating a step of performing a dye adsorption treatment to which the present invention is applied.

FIG. 3 includes views illustrating a step of performing the dye adsorption treatment to which the present invention is applied.

FIG. 4 includes views showing a configuration of an embodiment of a solar cell-cum-display device to which the present invention is applied.

FIG. 5 is a view showing an example of a solar cell-cum-display unit.

FIG. 6 includes views showing another configuration of an embodiment of a solar cell-cum-display device to which the present invention is applied.

FIG. 7 is a view showing an example of a solar cell-cum-display unit.

FIG. 8 is a view showing a configuration of an embodiment of a film-like solar cell to which the present invention is applied.

FIG. 9 is a view showing another configuration of an embodiment of a film-like solar cell to which the present invention is applied.

FIG. 10 is a view showing an example of a film-like solar cell.

### DESCRIPTION OF EMBODIMENTS

Embodiments of the present invention will now be described with reference to the drawings.

In the meantime, a process of producing a dye-sensitized solar cell is performed, for example, in accordance with steps (1) to (7) below.

(1) Laser scribing process treatment
(2) Screen printing treatment
(3) Annealing treatment
(4) Dye adsorption treatment
(5) Lamination treatment
(6) Electrolyte solution injection treatment
(7) Injection port sealing treatment

To explain briefly, in such a production process, first, a transparent substrate such as electrically conductive glass is subjected to laser processing by (1) laser scribing process treatment, whereby a patterned transparent substrate is obtained. Next, in (2) screen printing treatment, a predetermined paste is applied onto the transparent substrate by a screen printing method. Subsequently, baking is performed by heating in (3) annealing treatment at 100° C. to 600° C. for about one hour in an electric furnace, for example. Thus, a semiconductor electrode is obtained.

Subsequently, in (4) dye adsorption treatment, a predetermined dye is adsorbed onto the semiconductor electrode, and (5) lamination with a counter electrode, an anti-reflection film, and the like is performed. A predetermined electrolyte solution is then injected in (6) electrolyte solution injection treatment, and (7) an injection port is sealed. Thus, a dye-sensitized solar cell is obtained.

The dye-sensitized solar cell is produced through the production process described above. In producing a dye-sensitized solar cell of the present invention, in particular, the step of (4) dye adsorption treatment is a characteristic step. Therefore, the dye adsorption treatment will now be described by way of specific examples of [EXAMPLE 1] to [EXAMPLES 5].

### Example 1

In the steps (1), (2), and (3), which are steps preceding (4) dye adsorption treatment, a commercially available TiO₂ paste is applied onto commercially available FTO glass (15 Ω/square) by a screen printing method, and was baked at 500° C. for one hour. Thus, titanium oxide electrodes (average film thickness: 20 μm) having a strip-shaped pattern are obtained.

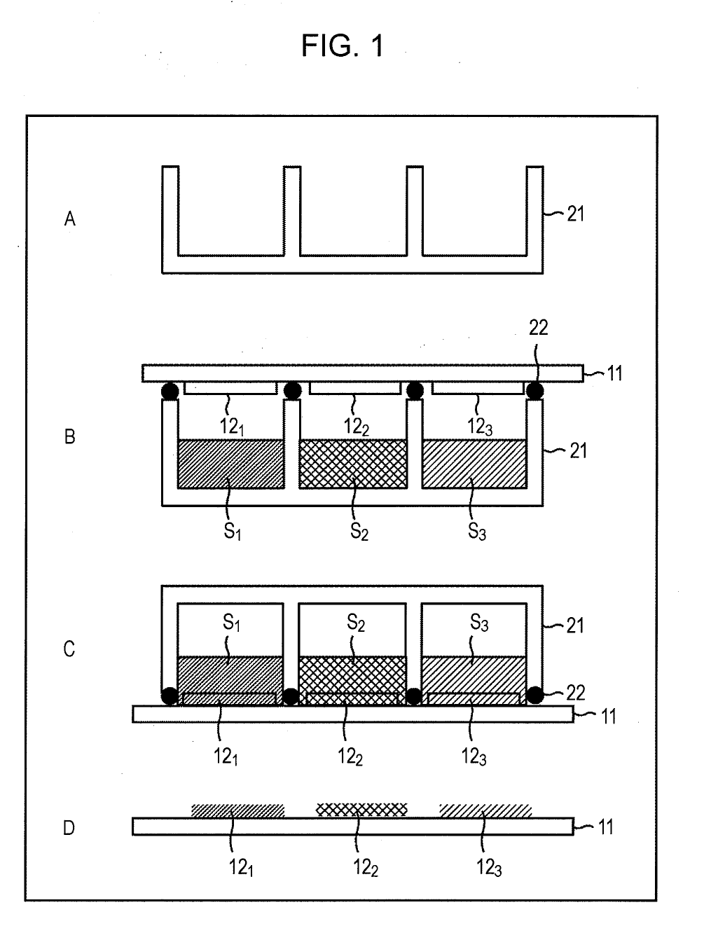

Next, the step proceeds to (4) dye adsorption treatment, and a treatment shown in the cross-sectional views of (4) dye adsorption treatment of FIG. 1 is performed. Note that, in FIG. 1, the strip-shaped titanium oxide electrodes obtained by the steps of (1) to (3) are described as semiconductor electrodes 12₁ to 12₃.

As shown in A of FIG. 1, an instrument 21 has a container shape (tray shape) having a bottom. In addition, the instrument 21 has partition walls having a predetermined shape. Different dye solutions can be put in respective sections divided by the partition walls. For example, in A of FIG. 1, the instrument 21 is divided into three sections, and three different types of dye solutions are put in these sections. Specifically, for example, three types of dyes of N719, Black dye, and D149 are each dissolved in a CH₃CN/t-BuOH mixed solution, thereby obtaining 0.3 mM dye solutions (dye solutions S₁, S₂, and S₃). Therefore, these dye solutions can be poured into the three respective sections of the instrument 21 shown in FIG. 1.

Subsequently, as shown in B of FIG. 1, a transparent substrate 11 is placed on upper edge portions (opening upper edge portion side) of the partition walls of the instrument 21, in which the three different types of dye solutions S₁ to S₃ are respectively put, such that a surface of the transparent substrate 11 on which the semiconductor electrodes 12₁ to 12₃ (titanium oxide electrodes) are formed is disposed on the lower side (instrument 21 side), thereby sealing the instrument 21. At this time, the transparent substrate 11 is boned to the instrument 21 with an adhesive 22 shown by black circles in the figure, whereby the transparent substrate 11 and the instrument 21 are laminated and fixed to each other.

Note that, as such a lamination method, not only a method using the adhesive 22 such as a UV-curable adhesive but also, for example, a pressure-bonding method using a material functioning as a gasket, such as a silicon rubber, can be employed. In this case, the silicon rubber may be bonded to the instrument 21, or a sheet-like rubber may be used. In addition, as the transparent substrate 11, for example, a glass substrate made of electrically conductive glass or the like, a transparent plastic substrate, a metal plate, or the like is used.

Subsequently, when the top and bottom of the sealed instrument 21 are inverted in the state in which the transparent substrate 11 and the instrument 21 are bonded to each other, the transparent substrate 11 and the instrument 21 are disposed in the state shown in C of FIG. 1. That is, by inverting the top and bottom of the instrument 21, the dye solutions S₁ to S₃ that have been located on the bottom side of the instrument 21 flow into the transparent substrate 11 side, and at the same time, the semiconductor electrodes 12₁ to 12₃ are filled with the dye solutions S₁ to S₃, respectively. Thus, respective dyes are adsorbed onto the semiconductor electrodes 12₁ to 12₃. At this time, a dye is adsorbed onto the semiconductor electrode 12₁ by the dye solution S₁, a dye is adsorbed onto the semiconductor electrode 12₂ by the dye solution S₂, and a dye is adsorbed onto the semiconductor electrode 12₃ by the dye solution S₃. In other words, a desired dye is adsorbed at a desired position on the semiconductor electrode. Furthermore, a selective dye adsorption can be performed by simply preparing the instrument 21, and thus performed easily.

Subsequently, after the instrument 21 and the transparent substrate 11 are allowed to stand as they are for 24 hours in the state of C of FIG. 1, the instrument 21 is removed from the transparent substrate 11. Thus, as shown in D of FIG. 1, the semiconductor electrodes 12₁ to 12₃ that are selectively colored with different dyes contained in the dye solutions S₁ to S₃, respectively, are formed on the transparent substrate 11.

Note that, as for the shape of the instrument 21 used in the step of (4) dye adsorption treatment, it is necessary that the partition walls have a height of at least 3 mm or more. This is because the amount of dyes contained in the dye solutions poured onto the semiconductor electrodes 12 is insufficient if the height of the partition walls is equal to or less than 3 mm. The upper limit of the height of the partition walls is not particularly limited as long as the height of the partition walls is 3 mm or more. The width of the partition walls is also not particularly limited, but is desirably 10 mm or less in terms of practical use. The reason for this is as follows. If the width of the partition walls is equal to or more than 10 mm, the area contributing to power generation in the solar cell area is reduced to a level that is not tolerable to practical use.

In addition, the time during which the instrument 21 and the transparent substrate 11 are allowed to stand in the state of C of FIG. 1 varies depending on the film thickness of the semiconductor electrodes 12₁ to 12₃. In a case of a small film thickness, adsorption can be performed in a short time, for example, 10 minutes, 15 minutes, 30 minutes, or the like. On the other hand, in a case of a large film thickness, for example, it takes 48 hours or more to perform adsorption. Furthermore, the standing time is also affected by a temperature. Accordingly, the time is preferably determined in consideration of both the film thickness and the temperature of a place where the work is performed. In addition, operations such as heating and stirring may be used if necessary.

Furthermore, after (4) dye adsorption treatment is finished, the subsequent steps (5), (6), and (7) are performed, whereby the semiconductor electrodes with the dyes obtained in the step of (4) are laminated to a platinum-sputtered counter electrode with a UV-curable adhesive, and an electrolyte solution is injected therein. Thus, a dye-sensitized solar cell is obtained. Accordingly, through the above steps, a dye-sensitized solar cell in which predetermined dyes are adsorbed at predetermined positions is obtained.

Note that, not only selective coloring in different types of colors but also selective coloring in different shades of one color (one type) of a dye can be performed by using the method of this [EXAMPLE 1]. In this case, the shades can be controlled by changing the adsorption time, the concentration of a dye solution, the type of solvent, and the like for each unit. In addition, by selectively coloring in different colors using the instrument 21, dyes representing, for example, characters, numbers, symbols, figures, or any combination thereof can be adsorbed onto the semiconductor electrodes. These also apply to other EXAMPLES described below.

### Example 2

In [EXAMPLE 1] described above, in addition to an example using the adhesive 22, an example of performing pressure-bonding using a gasket has been described as a method of laminating the instrument 21. As the pressure-bonding method, not only a mechanical pressure-bonding method but also a pressure-bonding method using atmospheric pressure, for example, a method in which the lamination is performed in a vacuum and the pressure is then returned to the atmospheric pressure can be adopted.

Specifically, an instrument 21 that has partition walls in which three types of dye solutions S₁ to S₃ similar to those of [EXAMPLE 1] are injected and that is provided with a silicon rubber layer on the outer circumferences of the partition walls is mechanically laminated to semiconductor electrodes 12₁ to 12₃ fabricated by a method similar to that of [EXAMPLE 1] (steps (1) to (3)). Subsequently, the pressure in the inner space of the instrument 21 that is set in a sealed state by the lamination is reduced with a vacuum pump, thereby achieving sufficient bonding. The top and bottom of this instrument 21 are inverted in that state as in [EXAMPLE 1], and the instrument 21 is then allowed to stand for 24 hours.

Subsequently, the semiconductor electrodes 12₁ to 12₃ inverted and located on the lower side of the instrument 21 are returned to the upper side again, furthermore, the inside of the instrument 21 is then returned to the atmospheric pressure, and a transparent substrate 11 is removed. Thus, the semiconductor electrodes 12₁ to 12₃ selectively colored with three types of dyes are obtained. Subsequently, the resulting semiconductor electrodes with the dyes are laminated to a platinum-sputtered counter electrode with a UV-curable adhesive, and an electrolyte solution is injected by a method similar to that of [EXAMPLE 1] (steps (5), (6), and (7)). Thus, a dye-sensitized solar cell is obtained.

### Example 3

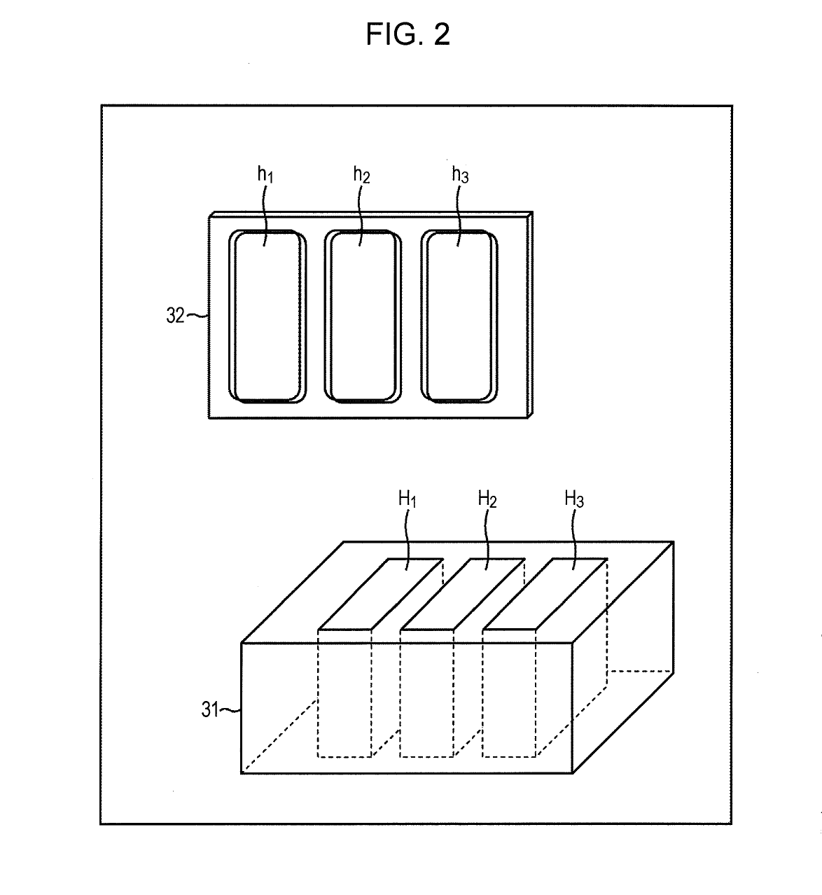

In [EXAMPLE 1] described above, a description has been made of a configuration in which dyes are adsorbed onto the semiconductor electrodes 12₁ to 12₃ by inverting the top and bottom of the instrument 21 shown in FIG. 1. However, dyes can be adsorbed without inverting members by using a jig 31 shown in FIG. 2. Note that, in FIG. 2, the drawing on the lower side is a perspective view of the jig 31, and the drawing on the upper side is a top view of a silicon rubber 32.

Specifically, the jig 31 having a hollow shape is mechanically pressure-bonded to semiconductor electrodes 12₁ to 12₃ fabricated by a method similar to that of [EXAMPLE 1] (steps (1) to (3)) with the silicon rubber 32 having hole portions h₁ to h₃ corresponding to hollow portions H₁ to H₃, respectively, of the jig 31. That is, at this time, the semiconductor electrodes 12₁ to 12₃ are located at the bottom of the jig 31 having the hollow shape. Subsequently, when three types of dye solutions S₁ to S₃ similar to those of [EXAMPLE 1] are injected into the three respective hollow portions H₁ to H₃ provided in the jig 31, dyes are adsorbed onto the semiconductor electrodes 12₁ to 12₃ that are pressure-bonded as the bottom of the jig 31 with the silicon rubber 32 therebetween.

Subsequently, by allowing the jig 31 etc. to stand as they are for 24 hours in that state, the semiconductor electrodes 12₁ to 12₃ that are selectively colored with the three types of dyes corresponding to the hollow shape of the jig 31 are obtained. Subsequently, the resulting semiconductor electrodes with the dyes are laminated to a platinum-sputtered counter electrode with a UV-curable adhesive, and an electrolyte solution is injected by a method similar to that of [EXAMPLE 1] (steps (5), (6), and (7)). Thus, a dye-sensitized solar cell is obtained.

### Example 4

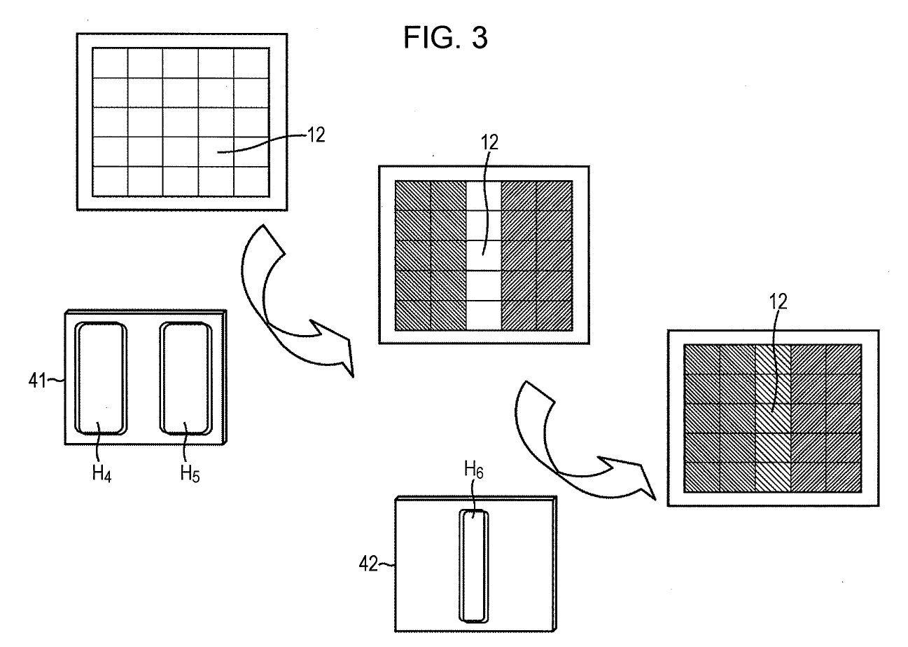

While dye adsorptions are all performed at one time in [EXAMPLE 1] described above, these dye adsorptions can be separately performed a plurality of times. Here, for example, with reference to FIG. 3, a description will be made by taking, as an example, a case where titanium oxide electrodes are obtained on one surface of 5 cm×5 cm by a method similar to that of [EXAMPLE 1].

Note that, in FIG. 3, the titanium oxide electrodes obtained by the steps (1) to (3) similar to those of [EXAMPLE 1] are described as semiconductor electrodes 12 composed of 5×5 squares arranged in the form of a grid corresponding to a size of 5 cm×5 cm of the titanium oxide electrodes (one square is one-centimeter square). In addition, FIG. 3 shows top views of a jig 41, a jig 42, and the semiconductor electrodes 12. As indicated by arrows in the figure, the semiconductor electrodes 12 are arranged in time series in a direction from the upper left in the figure to the lower right in the figure. Accordingly, in a description of FIG. 3, three states of the semiconductor electrodes 12 arranged in time series from the upper left in the figure to the lower right in the figure are referred to as a state 1, state 2, and state 3, respectively, in order from the upper left in the figure.

In this case, as shown in FIG. 3, of the jig 41 having the shape of a pattern 1 (a hole portion H₄ and a hole portion H₅ in FIG. 3) and the jig 42 having the shape of a pattern 2 (a hole portion H₆ in FIG. 3) different from the pattern 1, the jig 41 is first placed on the semiconductor electrodes 12 in the state 1.

Subsequently, dye solutions S₁ and S₂ are respectively injected into squares of a first column and a second column from the left in the figure and squares of a fourth column and a fifth column from the left in the figure located at positions corresponding to the hole portion H₄ and the hole portion H₅ provided in the jig 41 among the 5×5 squares on the semiconductor electrodes 12 in the state 1 obtained by the steps (1) to (3). More specifically, after the jig 41 is laminated to the semiconductor electrodes 12, the dye solutions S₁ and S₂ of N719 and Black dye are injected into the hole portion H₄ and the hole portion H₅, respectively, and the jig 41 and the semiconductor electrodes 12 are allowed to stand as they are for 24 hours. Thus, the dyes of shapes corresponding to the hole portion H₄ and the hole portion H₅ of the jig 41 are adsorbed onto the semiconductor electrodes 12.

Subsequently, by removing the jig 41, as shown in the semiconductor electrodes 12 in the state 2 of FIG. 3, a dye is adsorbed on the squares of the first and second columns (the region on the squares shown by right-downward hatching in the figure) by the dye solution S₁, and a dye is adsorbed on the squares of the fourth and fifth columns (the region on the squares shown by left-downward hatching in the figure) by the dye solution S₂. At this time, as is also apparent from the semiconductor electrodes 12 in the state 2, the semiconductor electrodes 12 are in a state in which no dye is adsorbed on the squares of the third column in the middle.

Next, a predetermined dye is adsorbed on the remaining third column in the middle of the semiconductor electrodes 12 using the jig 42. Specifically, after being rinsed with acetonitrile, the jig 42 is laminated to the semiconductor electrodes 12. A dye solution S₃ of D149 is injected into the hole portion H₆, and the jig 42 and the semiconductor electrodes 12 are allowed to stand as they are for 24 hours. Thus, the dye of a shape corresponding to the hole portion H₆ of the jig 42 is adsorbed onto the semiconductor electrodes 12.

Subsequently, by removing the jig 42, as shown in the semiconductor electrodes 12 in the state 3 of FIG. 3, the dye is adsorbed on the squares of the third column (the region on the squares shown by right-downward wide hatching in the figure) by the dye solution S₃. That is, the semiconductor electrodes 12 colored with the three types of dyes are obtained by selective coloring with the dyes in two stages using the jigs 41 and 42.

Subsequently, the resulting semiconductor electrodes with the dyes are laminated to a platinum-sputtered counter electrode with a UV-curable adhesive, and an electrolyte solution is injected by a method similar to that of [EXAMPLE 1] (steps (5), (6), and (7)). Thus, a dye-sensitized solar cell is obtained.

In this manner, when dyes are adsorbed, not only the adsorption is performed over the entire sections at one time but also the adsorption in some sections can be separately performed in several stages. Therefore, for example, even in the case where sections for selective coloring are adjacent to each other or such sections are not sufficiently separated from each other to an extent that a partition wall is provided therebetween, selective coloring with dyes can be easily performed by separately performing adsorption in several stages, as described in [EXAMPLE 4].

### Example 5

In [EXAMPLE 1] to [EXAMPLE 4] described above, a description has been made of an example in which the step of (4) dye adsorption treatment is performed on titanium oxide electrodes fabricated by the steps (1) to (3) described in [EXAMPLE 1]. However, the titanium oxide electrodes may be fabricated by another method.

Specifically, in the steps (1) to (3), which are steps preceding (4) dye adsorption treatment, 20 weight percent of a commercially available titanium oxide P25 is dispersed into gamma-butyrolactone, and a polyvinylidene fluoride-hexafluoropropylene (PVDF-HFP) copolymer is further added thereto in an amount of 30 weight percent relative to the titanium oxide, and the resulting mixture is stirred while heating at about 60° C. Thus, a homogeneous solution is obtained. This solution is applied onto a PEN substrate with ITO by a blade coating method, and the substrate is dried at 120° C. for one hour. Furthermore, this substrate is pressed using a roll press machine. Thus, titanium oxide electrodes having a size of 5 cm×5 cm are obtained on the PEN substrate.

Subsequently, these titanium oxide electrodes are treated by, for example, a method similar to that of [EXAMPLE 4] described above to obtain titanium oxide electrodes colored with three types of dyes. The titanium oxide electrodes are then treated by a method similar to that of [EXAMPLE 1] (steps (5), (6), and (7)). Thus, a dye-sensitized solar cell is obtained. That is, in this [EXAMPLE 5], the titanium oxide electrodes are formed on a flexible substrate such as a PEN substrate or the like, and thus a more flexible dye-sensitized solar cell can be fabricated.

As described above, any of the treatments described in [EXAMPLE 1] to [EXAMPLE 5] described above is performed in (4) dye adsorption treatment among the steps (1) to (7) of the process of producing a dye-sensitized solar cell. Next, details of dye-sensitized solar cells produced through these steps will be described.

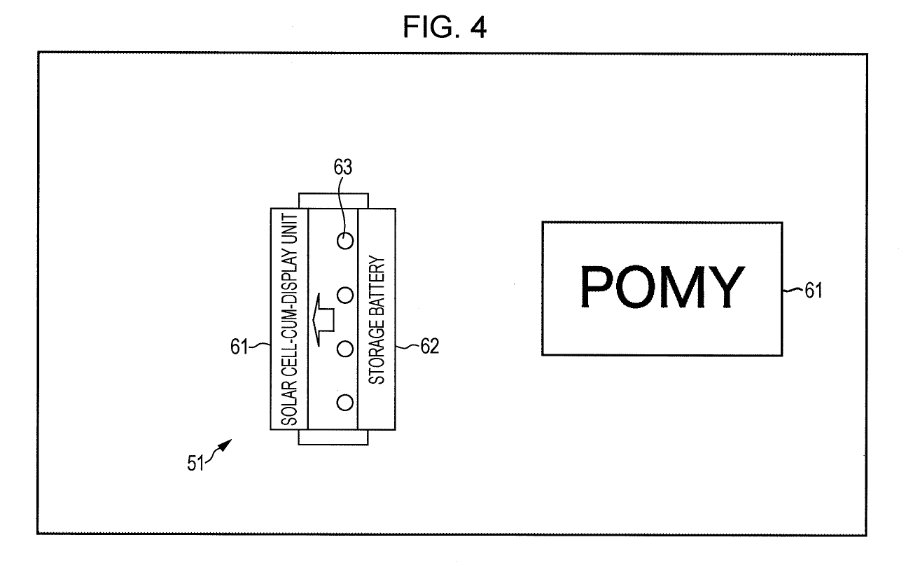

FIG. 4 shows an example of a dye-sensitized solar cell produced when (4) dye adsorption treatment is performed using any of the methods described in [EXAMPLE 1] to [EXAMPLE 4].

Note that, in the cross-sectional view on the left side of FIG. 4, a solar cell-cum-display unit 61 that has both a function of a solar cell and a function of a display unit corresponds to a dye-sensitized solar cell produced by the steps (1) to (7) described above. In the solar cell-cum-display unit 61, as shown in the front view on the right side of FIG. 4, a dye is adsorbed so that characters “POMY” are identifiable. A viewer can identity the characters without being aware that the display unit is a solar cell. That is, the solar cell-cum-display unit 61 is seen by the viewer as a natural part of the scenery in which the characters “POMY” are simply displayed.

In addition, as shown in FIG. 4, in a solar cell-cum-display device 51, electric power generated in the solar cell-cum-display unit 61 is stored in a storage battery 62 connected to the solar cell-cum-display unit 61. Furthermore, the electric power stored in this storage battery 62 is supplied to a light source 63 composed of fluorescent lamps or the like, whereby the solar cell-cum-display unit 61 is irradiated with light emitted from the light source 63. Thus, in the solar cell-cum-display device 51, a self-contained power generation can be realized in which light is applied from the light source 63 in addition to sunlight, and electrical energy generated from the light is used for illuminating light, and this is also very effective in terms of energy saving.

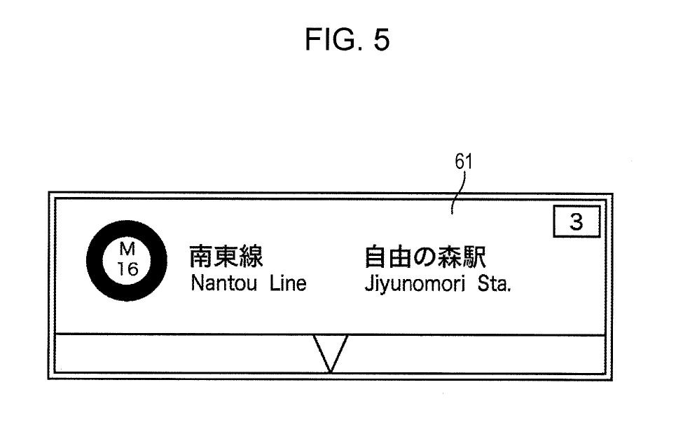

Specifically, for example, as shown in FIG. 5, when the solar cell-cum-display device 51 is used as a station name indication board installed in a station platform, users of the station recognize the indication board as a simple indication board showing the station name. However, since the solar cell-cum-display device 51 has the configuration shown in FIG. 4, in reality, the solar cell-cum-display device 51 also has a function of a solar cell. In the case of the example shown in FIG. 5, a dye representing characters such as “Nantou Line Jiyunomori Sta.” and the like is adsorbed on the solar cell-cum-display unit 61 using any one of the methods described in [EXAMPLE 1] to [EXAMPLE 4].

Specifically, in the inner portion of the station name indication board shown in FIG. 5, the solar cell-cum-display unit 61 is irradiated with the light source 63, whereby the station name on the indication board is irradiated. The illuminating light is converted into electric power by the solar cell-cum-display unit 61. Furthermore, the electric power is stored in the storage battery 62, and thus the light source 63 irradiates the station name on the indication board using the electric power stored in the storage battery 62. Note that, at this time, the solar cell-cum-display unit 61 may generate electric power not only from the illuminating light emitted from the light source 63 but also from sunlight, and electric power obtained therefrom may be stored in the storage battery 62.

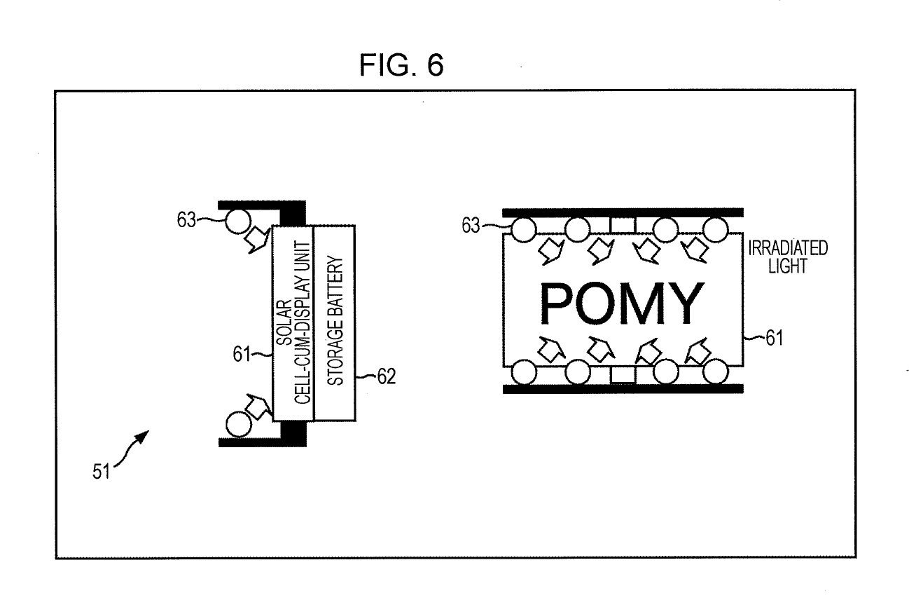

Furthermore, in the solar cell-cum-display device 51, instead of providing the light source 63 inside thereof as shown in FIG. 4, electric power may be generated from illuminating light emitted from a light source 63 provided on the display unit surface side of a solar cell-cum-display unit 61, and stored in a storage battery 62, as shown in FIG. 6. In this case, as shown in the cross-sectional view on the left side of FIG. 6, the solar cell-cum-display unit 61 generates electric power not only from the illuminating light emitted from the light source 63 but also from sunlight, and stores the electric power in the storage battery 62. In addition, as shown in the front view on the right side of FIG. 6, a dye is adsorbed on the solar cell-cum-display unit 61 similarly to FIG. 4 using any one of the methods described in [EXAMPLE 1] to [EXAMPLE 4] so that characters “POMY” are identifiable.

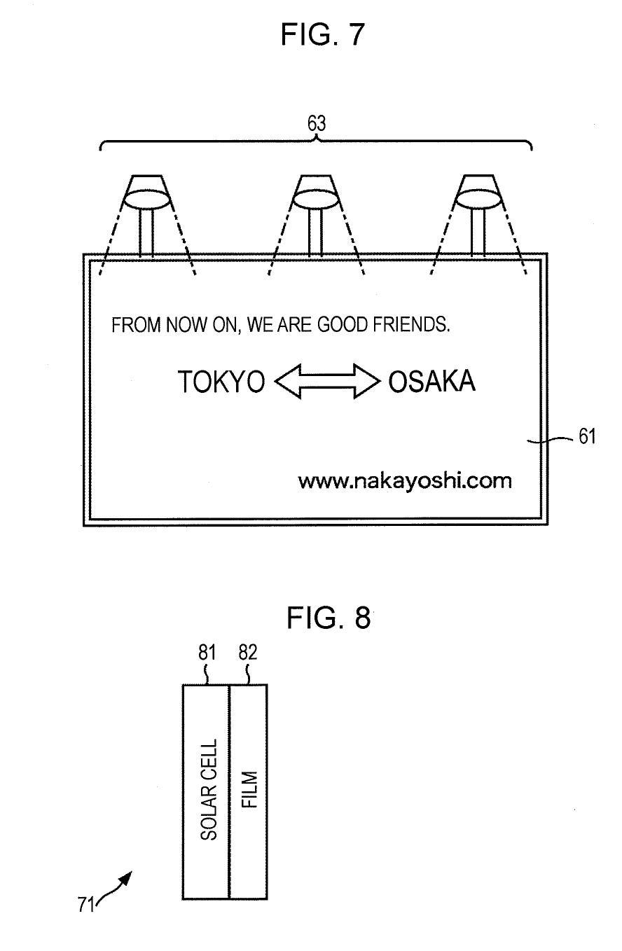

Specifically, for example, as shown in a signboard of FIG. 7, a predetermined dye is adsorbed onto semiconductor electrodes of a solar cell-cum-display unit 61 so that, for example, a character string “From now on, we are good friends . . . ” or the like is formed. In addition, the display unit surface having the character string thereon also has a function of a solar cell. Accordingly, as shown in FIG. 6, the solar cell-cum-display unit 61 can generate electric power from the illuminating light emitted from the light source 63 or sunlight, and store the electric power in the storage battery 62.

Incidentally, in this embodiment, the station name indication board of FIG. 5 and the signboard of FIG. 7 have been described as specific examples of the solar cell-cum-display device 51. Of course, the solar cell-cum-display device 51 can also be applied to other products. For example, the solar cell-cum-display device 51 can also be applied to car card advertising, advertising signs at stations, automatic vending machines, walls and columns of offices, internal illumination-type display devices, alarm display devices, guidance display devices, road signs, and self-luminous-type display devices. That is, in the solar cell-cum-display device 51, a display body representing characters, numbers, symbols, figures, or any combination thereof is formed on the display unit surface of the solar cell-cum-display unit 61 in accordance with the form of use.

Furthermore, it has been described that, in the solar cell-cum-display devices 51 shown in FIGS. 4 and 6, electric power generated by the solar cell-cum-display unit 61 is stored in the storage battery 62. Alternatively, the electric power generated from the solar cell-cum-display unit 61 may be directly supplied to the light source 63 without providing the storage battery 62.

As described above, in the solar cell-cum-display device 51, the solar cell-cum-display unit 61 having only a thickness of the size of one or two glass substrates or transparent substrates such as transparent plastic substrates can combine a display unit and a power generation unit of a solar cell. As a result, the structure is not complex, as compared with the case where the display unit and the power generation unit are separately formed. Furthermore, a very natural scenery can be realized in which the presence of a solar cell is not recognized when the display unit is viewed.

Furthermore, by adopting [EXAMPLE 1] to [EXAMPLE 4] in the step of (4) dye adsorption treatment in the process of producing a dye-sensitized solar cell, it is possible to produce a solar cell-cum-display device 51 having excellent design quality in which the shape and the color tone can be freely determined.

Furthermore, by using a dye-sensitized solar cell that exhibits a satisfactory power generation efficiency in indoor light, as compared with silicon-based solar cells, it is possible to utilize not only sunlight but also illuminating light. Accordingly, the solar cell-cum-display device 51 can be installed not only outdoors but also indoors.

A description has been made of examples of a dye-sensitized solar cell produced when the treatment is performed by any one of the methods described in [EXAMPLE 1] to [EXAMPLE 4]. Next, a description will be made of a dye-sensitized solar cell produced when the treatment is performed by the remaining method described in [EXAMPLE 5].

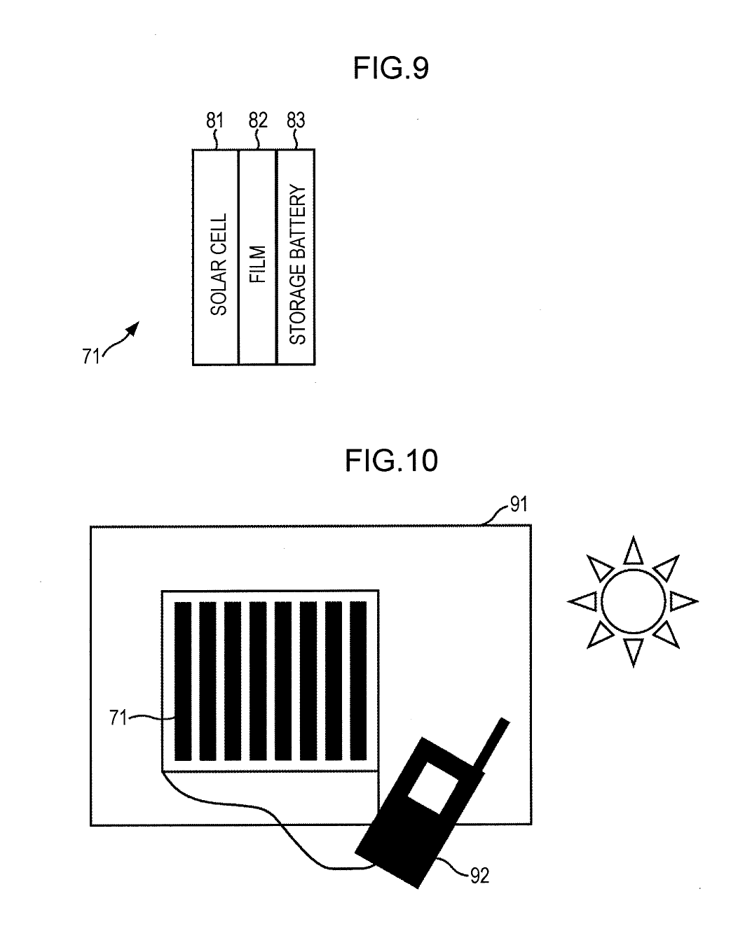

FIGS. 8 and 9 each show an example of a dye-sensitized solar cell produced when (4) dye adsorption treatment is performed by the method described in [EXAMPLE 5].

In FIG. 8, a film-like solar cell 71 including a solar cell 81 and a film 82 corresponds to a dye-sensitized solar cell produced by the steps (1) to (7) described above. That is, the film-like solar cell 71 is produced by, for example, fabricating titanium oxide electrodes on a film substrate such as a PEN substrate, and selectively coloring the titanium oxide electrodes with various types of dyes, as described in [EXAMPLE 5]. Thus, since the film-like solar cell 71 includes a dye-sensitized solar cell formed on a film that can be attached and detached any number of times, the film-like solar cell 71 can be freely attached to, for example, a window, a tile, or the like to generate power.

This film-like solar cell 71 may be configured so that, as shown in FIG. 8, the film 82 functions as a part of a substrate on which the solar cell 81 is formed. Alternatively, as shown in FIG. 9, the film-like solar cell 71 may have a configuration in which the solar cell 81 and the film 82 are further combined with a storage battery 83. That is, in the film-like solar cell 71 shown in FIG. 9, electric power is generated from sunlight or illuminating light by the solar cell 81 disposed on the film 82, and the electric power is stored in the storage battery 83.

Specifically, for example, as shown in FIG. 10, when the film-like solar cell 71 is formed as a solar cell sticker for charging, the solar cell sticker capable of being attached to a window 91, a rechargeable battery of a mobile phone handset 92 can be charged by connecting the mobile phone handset 92 to the film-like solar cell 71 (solar cell sticker for charging) attached to the window 91. Here, of course, the window 91 may be a window of a building such as a house. Alternatively, for example, the film-like solar cell 71 may be attached to a window glass of a vehicle such as a bus or a train. In such a case, a passenger can charge the mobile phone handset 92 during a ride on the vehicle such as a bus by utilizing the journey time. In this case, since a large space is not necessary, charging of a device can be performed even during a ride on a vehicle without consideration of space and without bothering other passengers.

Note that a dye-sensitized solar cell, whose power generation efficiency does not tend to depend on the incident angle of light and which exhibits a high power generation efficiency in indoor light, is suitable as a solar cell that is attached to a window glass to use indoor light. Accordingly, the film-like solar cell 71 is suitably used in a state in which the film-like solar cell 71 is attached to a window 91, as described as the solar cell sticker for charging.

As described above, when a user desires to charge a mobile device that requires charging, such as a mobile phone handset, charging of the device can be performed by attaching the film-like solar cell 71 to a desired place. Furthermore, the attached film-like solar cell 71 can be detached and reused any number of times.

Furthermore, as shown in the example of FIG. 10, since the film-like solar cell 71 can be attached to the window 91 for example, power generation using both indoor light and sunlight can be realized. In addition, it is sufficient that the film-like solar cell 71 is simply attached to the window 91, and thus there is also an advantage that the film-like solar cell 71 can be detached from the window 91 after use without fouling the window 91.

Furthermore, since the film-like solar cell 71 can be selectively colored with dyes by the method described in [EXAMPLE 5], by attaching the film-like solar cell 71, which has been selectively colored with the dyes, to a window of a car or a shop, the film-like solar cell 71 can also exerts a function of an advertisement. That is, in the film-like solar cell 71, a display body representing characters, numbers, symbols, figures, or any combination thereof is formed on the display unit surface of the solar cell-cum-display unit 81 in accordance with the form of use.

As described above, since the film-like solar cell 71 is fabricated from a film that can be attached and detached any number of times, power generation can be performed by attaching the film-like solar cell 71 to a window, a tile, or the like using sunlight and illuminating light. The generated power can be used for charging a rechargeable battery of a mobile device, for example. Furthermore, since the film-like solar cell 71 can be attached to a side wall, such as a window, without placing it on a floor, a small space can be effectively used.

In addition, in the step of (4) dye adsorption treatment of the process of producing a dye-sensitized solar cell, by adopting [EXAMPLE 5], a film having design quality in which the shape and the color tone can be freely determined can be formed, and the film can also be used in advertisements, signs, and the like besides interior goods. Furthermore, by using a dye-sensitized solar cell that exhibits a satisfactory power generation efficiency in indoor light, as compared with silicon-based solar cells, it is possible to utilize not only sunlight but also illuminating light. Accordingly, the film-like solar cell 71 can be installed not only outdoors but also indoors.

Furthermore, by using a dye-sensitized solar cell, for example, see-through or multicolor cells can be fabricated, and thus such cells can also satisfactorily function as interior goods beyond the concept of solar cells. In addition, when the film-like solar cell 71 is carried, it can be folded or rolled. This is also advantageous in that the film-like solar cell 71 can be easily carried without occupying a large space.

Incidentally, in the above embodiments, it is described that the electric power generated by the dye-sensitized solar cell is stored in a storage battery, but the electric power may be charged in another object. For example, the electric power may be charged in a capacitor.

In addition, embodiments of the present invention are not limited to the embodiments described above, and various modifications can be made within a range that does not deviate from the gist of the present invention. For example, the numerical values, structures, shapes, materials, raw materials, processes, and the like cited in the above embodiments are merely exemplifications, and numerical values, structures, shapes, materials, raw materials, and processes different from those may be used, as needed.

Furthermore, in the above embodiments, a photoelectric conversion element has been described using a dye-sensitized solar cell as an example. However, the present invention can also be applied to solar cells other than dye-sensitized solar cells, and photoelectric conversion elements other than solar cells.

### REFERENCE SIGNS LIST

11 transparent substrate, 12₁ to 12₃ and 12 semiconductor electrode, 21 instrument, 22 adhesive, 31 jig, 32 silicon rubber, 41 jig, 42 jig, S₁ to S₃ dye solution, H₁ to H₃ hollow portion, h₁ to h₃ hole portion, H₄ to H₆ hole portion, 51 solar cell-cum-display device, 61 solar cell-cum-display unit, 62 storage battery, 63 light source, 71 film-like solar cell, 81 solar cell, 82 film, 83 storage battery

1. An electronic device comprising:
a photoelectric conversion element including a predetermined display body formed by adsorbing a predetermined dye onto a semiconductor electrode.

2. The electronic device according to claim 1, further comprising:
a light source that irradiates the display body,
wherein the photoelectric conversion element generates electric power from light radiated from the light source and supplies the electric power to the light source, and
the light source is driven by the electric power supplied from the photoelectric conversion element.

3. The electronic device according to claim 2, further comprising:
a power storage unit that stores the electric power generated by the photoelectric conversion element,
wherein the photoelectric conversion element generates electric power from light radiated from the light source and stores the electric power in the power storage unit, and
the light source is driven by the electric power stored in the power storage unit.

4. The electronic device according to claim 1, wherein the display body represents a character, a number, a symbol, a figure, or any combination thereof.

5. The electronic device according to claim 1,
wherein the photoelectric conversion element is a dye-sensitized solar cell.

6. An electronic device comprising:
a photoelectric conversion element formed on a substrate that can be attached to and detached from an object having a predetermined shape.

7. The electronic device according to claim 6,
wherein the substrate is a film that can be attached and detached any number of times.

8. The electronic device according to claim 6,
wherein the photoelectric conversion element is attached to a window or a tile with the substrate therebetween, generates electric power from sunlight or illuminating light, and supplies the electric power to a power storage unit installed in the mobile device connected to the photoelectric conversion element.

9. The electronic device according to claim 6, further comprising:
a power storage unit that stores electric power generated by the photoelectric conversion element.

10. The electronic device according to claim 6,
wherein the photoelectric conversion element includes a predetermined display body formed by adsorbing a predetermined dye onto a semiconductor electrode.

11. The electronic device according to claim 10, wherein the display body represents a character, a number, a symbol, a figure, or any combination thereof.

12. The electronic device according to claim 6,
wherein the photoelectric conversion element is a dye-sensitized solar cell.
